(19) United States
(12) Patent Application Publication
(10) Pub. No.: US 2011/0042678 A1
(43) Pub. Date: Feb. 24, 2011

(54) Pad area, organic light emitting diode display device having the same, and method of fabricating the same

(75) Inventors: Jong-Yun Kim, Yongin-City (KR); Il-Jeong Lee, Yongin-City (KR)

Correspondence Address: ROBERT E. BUSHNELL & LAW FIRM, 2029 K STREET NW, SUITE 600, WASHINGTON, DC, 20006-1004, US

(73) Assignee: SAMSUNG MOBILE DISPLAY CO., LTD, Yongin-City (KR)

(21) Appl. No.: 12/805,856

(22) Filed: Aug. 20, 2010

(30) Foreign Application Priority Data
Aug. 21, 2009 (KR) 2009-0077603

(51) Int. Cl. H01L 33/16; H01L 29/04; H01L 21/28

(52) U.S. Cl. 257/72; 257/75; 438/34; 257/E29.003; 257/E33.003; 257/E21.158

(57) ABSTRACT

An organic light emitting diode (OLED) display device having a pixel area and a pad area. The pad area includes a silicon layer pattern arranged on the substrate, an insulating layer arranged on the silicon layer pattern, an interconnection layer arranged on the insulating layer, and a protective layer surrounding an edge of the interconnection layer and having an opening exposing the interconnection layer. Since a surface area of the interconnection layer is increased due to a roughness of the underlying polycrystalline silicon layer pattern in the pad area, resulting in increased contact area and reduced contact resistance between parts configured to operate a flat panel display device and the interconnection layer is increased.

### CLAIM OF PRIORITY

This application makes reference to, incorporates the same herein, and claims all benefits accruing under 35 U.S.C. §119 from an application earlier filed in the Korean Intellectual Property Office on 21 Aug. 2009 and there duly assigned Serial No. 10-2009-77603.

### BACKGROUND OF THE INVENTION

1. Field of the Invention

The present invention relates to a pad area, an organic light emitting diode (OLED) display device having the same, and a method of fabricating the same, and more particularly, to a pad area capable of reducing a contact resistance between parts configured to operate a flat panel display device and an interconnection layer.

2. Description of the Related Art

Recently, flat panel display devices such as liquid crystal display (LCD) devices, organic light emitting diode (OLED) display devices, or plasma display panels (PDPs) have attracted attention as alternatives to overcome disadvantages of conventional display devices such as cathode-ray tube display devices.

LCD devices have excellent characteristics such as high resolution, good color display, high picture quality, and low power consumption. Moreover, OLED display devices have a simple structure due to self-emission of organic materials, and have high optical efficiency, direct current and low voltage, and high response speed. Field emission display (FED) devices have excellent characteristics such as high resolution and wide viewing angle, and PDPs also have excellent characteristics such as high brightness, high emission efficiency and wide viewing angle.

These flat panel display devices may be fabricated by forming devices on a transparent insulating substrate made out of glass or plastic.

Here, to operate the flat panel display device, parts configured to generate several control or data signals can be mounted on a predetermined region of the substrate on which the flat panel display device is fabricated. Examples of techniques for mounting the parts include a chip on glass (COG) technique and a chip on flexible printed circuit (FPC) (COF) technique. The COG technique is a technique of directly mounting a part such as an integrated circuit (IC) chip on a substrate, whereas the COF technique is a technique of mounting a part such as an IC chip on a film such as a polyimide film, and then attaching the film on a substrate.

Here, to mount the part on the substrate on which the flat panel display device is to be fabricated by the COG or COF technique, pads in electrical communication with each other are needed. However, an insufficient contact area in the pad structure using the COG or COF technique causes improper contact therewith, resulting in an increase in contact resistance.

### SUMMARY OF THE INVENTION

Therefore, the present invention provides a pad area capable of reducing a contact resistance between parts configured to operate a flat panel display device and an interconnection layer.

According to one aspect of the present invention, there is provided a pad area that includes a substrate, a silicon layer pattern arranged on the substrate, an insulating layer arranged on the silicon layer pattern, an interconnection layer arranged on the insulating layer and a protective layer surrounding an edge of the interconnection layer and having an opening exposing the interconnection layer. The silicon layer pattern, the insulating layer and the interconnection layer can have uneven surfaces. The silicon layer pattern can be a polycrystalline silicon layer pattern.

According to another aspect of the present invention, there is provided an organic light emitting diode (OLED) display device that includes a substrate having a pixel area and a pad area, the pad area including a silicon layer pattern arranged on the substrate, an insulating layer arranged on the silicon layer pattern, an interconnection layer arranged on the insulating layer and a protective layer surrounding an edge of the interconnection layer and having an opening exposing the interconnection layer. The silicon layer pattern, the insulating layer and the interconnection layer can have uneven surfaces.

The pixel area can include a silicon layer pattern arranged on the substrate and having source and drain regions, a gate insulating layer arranged on an entire surface of the substrate having the silicon layer pattern, a gate electrode arranged on the gate insulating layer, an interlayer insulating layer arranged on the gate electrode and source and drain electrodes electrically connected to the source and drain regions respectively of the silicon layer pattern in the pixel area through contact holes arranged in the interlayer insulating layer. The insulating layer in the pad area can be the gate insulating layer, and the interconnection layer in the pad area is can include a same material as that of the gate electrode. The insulating layer in the pad area can be the interlayer insulating layer, and the interconnection layer in the pad area can include a same material as that of the source and drain electrodes. The silicon layer pattern can be a polycrystalline silicon layer pattern.

According to still another aspect according to the present invention, there is provided a method of fabricating an OLED display device that includes providing a substrate having a pixel area and a pad area, forming an amorphous silicon layer on an entire surface of the substrate, forming a polycrystalline silicon layer by crystallizing the amorphous silicon layer, forming polycrystalline silicon layer patterns at predetermined regions of the pixel and pad areas by patterning the polycrystalline silicon layer, the polycrystalline silicon layer pattern in the pixel area having source and drain regions and a channel region, forming a gate insulating layer on the entire surface of the substrate having the polycrystalline silicon layer patterns, applying a gate electrode material on the gate insulating layer, and forming a gate electrode corresponding to the channel region of the polycrystalline silicon layer pattern in the pixel area and an interconnection layer corresponding to the polycrystalline silicon layer pattern in the pad area by patterning the gate electrode material. The crystallizing the amorphous silicon layer into the polycrystalline silicon layer can be performed using a laser. The crystallizing can be performed by an excimer laser annealing (ELA) technique. The interconnection layer can have uneven surface.

According to yet another aspect of the present invention, there is provided a method of fabricating an OLED display device that includes providing a substrate having a pixel area and a pad area, forming an amorphous silicon layer on an entire surface of the substrate, forming a polycrystalline silicon layer by crystallizing the amorphous silicon layer, forming polycrystalline silicon layer patterns in predetermined regions of the pixel and pad areas respectively by patterning the polycrystalline silicon layer, the polycrystalline silicon layer pattern in the pixel area having source and drain regions, forming an interlayer insulating layer on the entire surface of the substrate having the polycrystalline silicon layer patterns, applying a material for source and drain electrodes to the pixel area and the pad area and forming the source and drain electrodes electrically connected to the source and drain regions respectively of the polycrystalline silicon layer pattern in the pixel area through contact holes formed in the interlayer insulating layer and forming an interconnection layer corresponding to the polycrystalline silicon layer pattern in the pad area by patterning the material for source and drain electrodes. The crystallizing the amorphous silicon layer into the polycrystalline silicon layer can be performed using a laser. The crystallizing can be performed by an excimer laser annealing technique

### BRIEF DESCRIPTION OF THE DRAWINGS

A more complete appreciation of the invention and many of the attendant advantages thereof, will be readily apparent as the same becomes better understood by reference to the following detailed description when considered in conjunction with the accompanying drawings in which like reference symbols indicate the same or similar components, wherein:

FIG. 1 is a plan view of an organic light emitting diode (OLED) display device having a pad area according to the present invention;

FIG. 2A is a cross-sectional view of the pad area according to the present invention;

FIG. 2B is a schematic view showing an increased contact area of the pad of FIG. 2A;

FIGS. 3A through 3G are cross-sectional views showing a process of fabricating an OLED display device having a pad area according to a first exemplary embodiment according to the present invention; and

FIG. 4 is a cross-sectional view of an OLED display device having a pad area according to a second exemplary embodiment of the present invention.

### DETAILED DESCRIPTION OF THE INVENTION

The present invention will now be described more fully hereinafter with reference to the accompanying drawings, in which exemplary embodiments of the invention are shown. Like reference numerals denote like elements throughout the specification, and when one part is “connected to” another part, these parts may be “directly connected” to each other, or “electrically connected” to each other having a third part therebetween. Moreover, in the drawings, thicknesses of layers and regions are exaggerated for clarity.

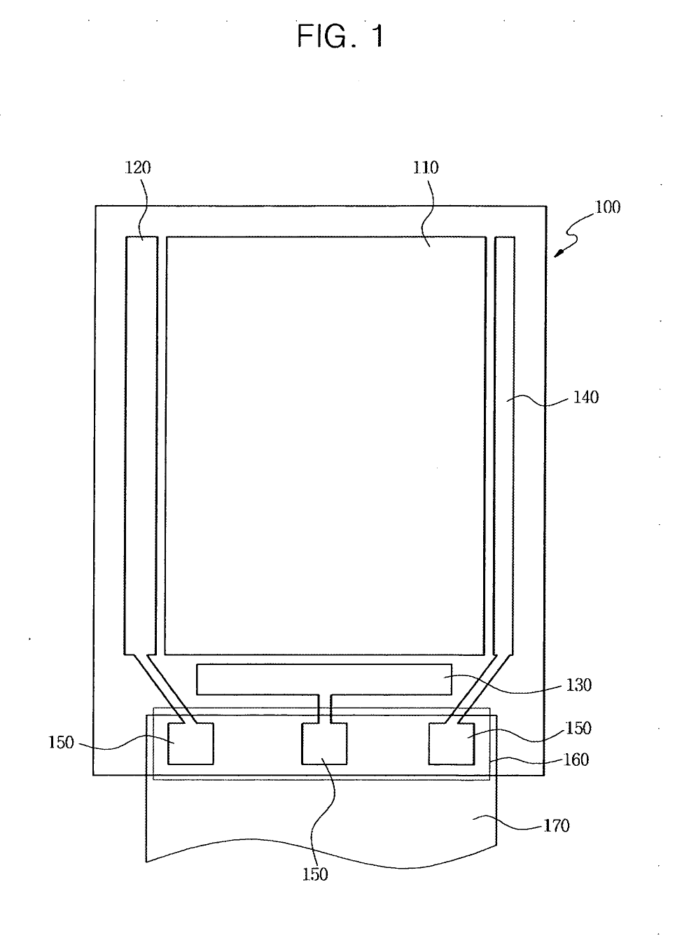

FIG. 1 is a plan view of an organic light emitting diode (OLED) display device having a pad area according to the present invention.

Referring to FIG. 1, a pixel area 110 is arranged on a transparent insulating substrate 100 made out of glass or plastic, a scan driver 120 and a data driver 130 configured to apply signals to the pixel area 110, and a common power bus line 140 configured to apply common power is arranged at an edge of the pixel area 110.

A pad area 160 having several pads 150 connected to the scan driver 120, data driver 130 and common power bus line 140 is arranged at a lower portion of the substrate in order to provide signals or power from an external COG or COF.

Here, while a flexible circuit board (FCB) 170 of COF is in contact with a pad 150 in the pad area 160 of FIG. 1, an IC chip can be equipped to the pad 150 of the substrate 100 if necessary.

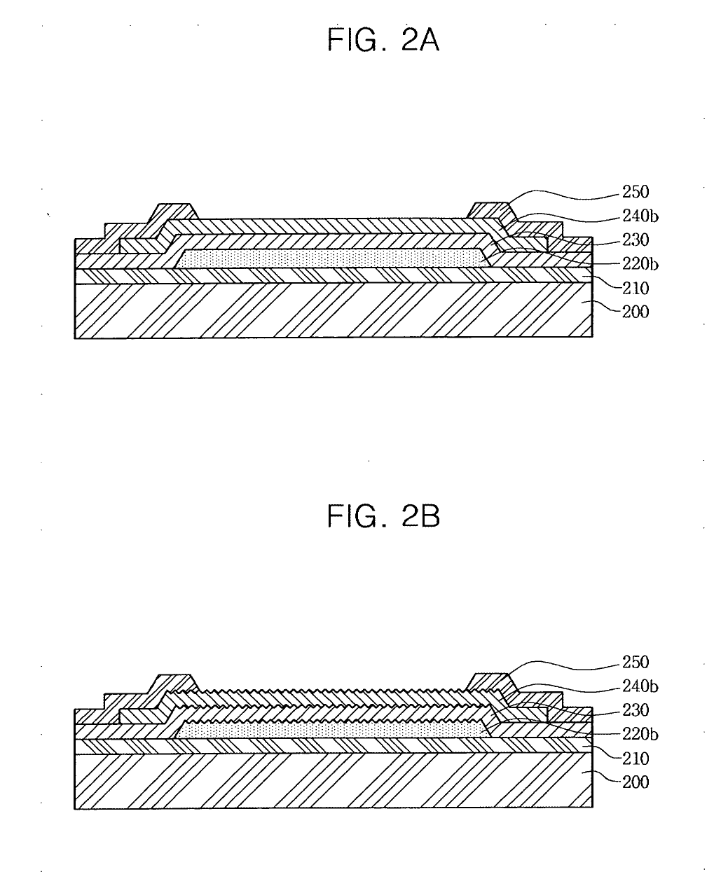

FIG. 2A is a cross-sectional view of a pad area according to the present invention. Here, FIG. 2A shows a cross-section of the pad 150 of FIG. 1, but the FCB 170 is not shown herein.

Referring to FIG. 2A, a buffer layer 210 can be arranged on an insulating substrate 200 made out of glass or plastic. A silicon layer pattern 220b is arranged on the buffer layer 210. The silicon layer pattern 220b can be a polycrystalline silicon layer pattern, which can be located in a pad area by forming an amorphous silicon layer on the buffer layer, crystallizing the amorphous silicon layer into a polycrystalline silicon layer by one of various crystallization techniques, and patterning the polycrystalline silicon layer to produce a polysilicon layer pattern 220b in the pad area along with forming a semiconductor layer in a pixel area. This process will be described in detail below.

An insulating layer 230 is arranged on the polycrystalline silicon layer pattern 220b. The insulating layer 230 can be a gate insulating layer or interlayer insulating layer, which will be described in detail below.

An interconnection layer 240b composed of a conductor is arranged on the insulating layer 230. The interconnection layer 240b can be produced by patterning a gate electrode material or a material for source and drain electrodes, which will be described in detail below. A protective layer 250 surrounding an edge of the interconnection layer 240b and having an opening exposing the interconnection layer 240b is arranged on the interconnection layer 240b.

FIG. 2B is a schematic view showing an increased contact area of a pad of FIG. 2A. Referring to FIG. 2B, as described above, the silicon layer pattern 220b is arranged on the buffer layer 210, and corresponds to the polycrystalline silicon layer pattern.

The polycrystalline silicon layer pattern 220b is produced by crystallizing the amorphous silicon layer into the polycrystalline silicon layer, and patterning the polycrystalline silicon layer. The polycrystalline silicon layer pattern 220b as shown in FIG. 2B has a roughness of several nanometers to several micrometers on its surface.

Accordingly, the insulating layer 230 formed on the polycrystalline silicon layer pattern 220b has a roughness similar to that of polycrystalline silicon layer pattern 220b, and the interconnection layer 240b also has a similar to that of the insulating layer 230.

Thus, due to the influence of the morphology of the roughness formed on the polycrystalline silicon layer pattern 220b to the interconnection layer 240b, a surface area of the interconnection layer 240b is increased. As a result, when parts configured to generate control or data signals are attached to the flat panel display device, a contact area between these parts and the interconnection layer is increased, thereby reducing contact resistance.

In other words, as shown in FIGS. 2A and 2B, since the pad allows the polycrystalline silicon layer pattern 220b to remain under the interconnection layer, a contact between the pad 150 and the FCB 170, as shown in FIG. 1, can be effectively achieved.

Here, the polycrystalline silicon layer pattern 220b can be formed along with forming the semiconductor layer pattern in the pixel area, and thus no additional process or mask is needed.

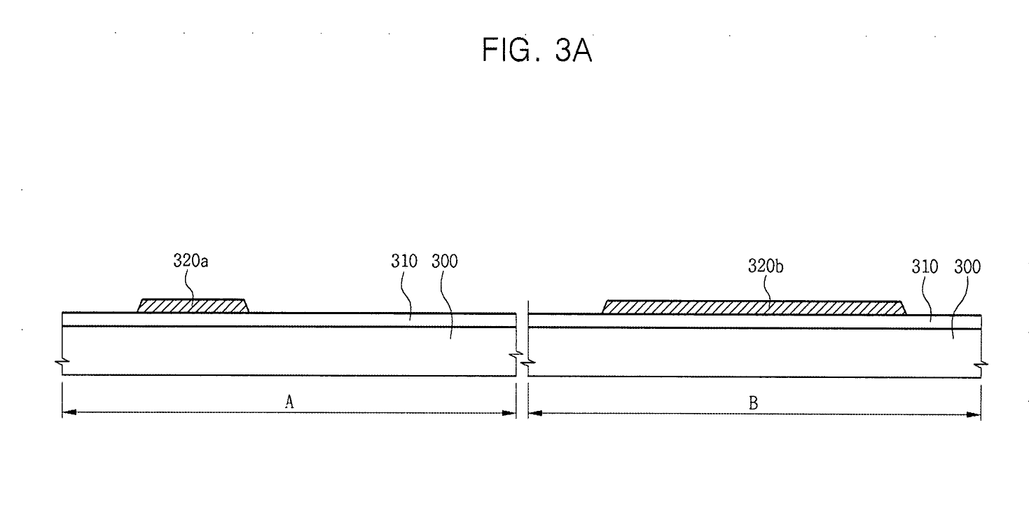

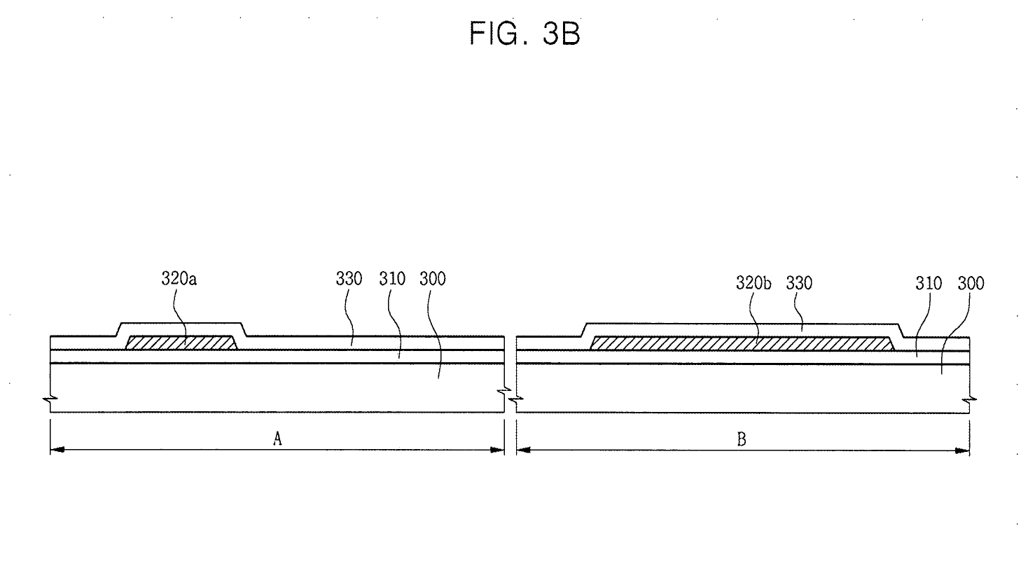

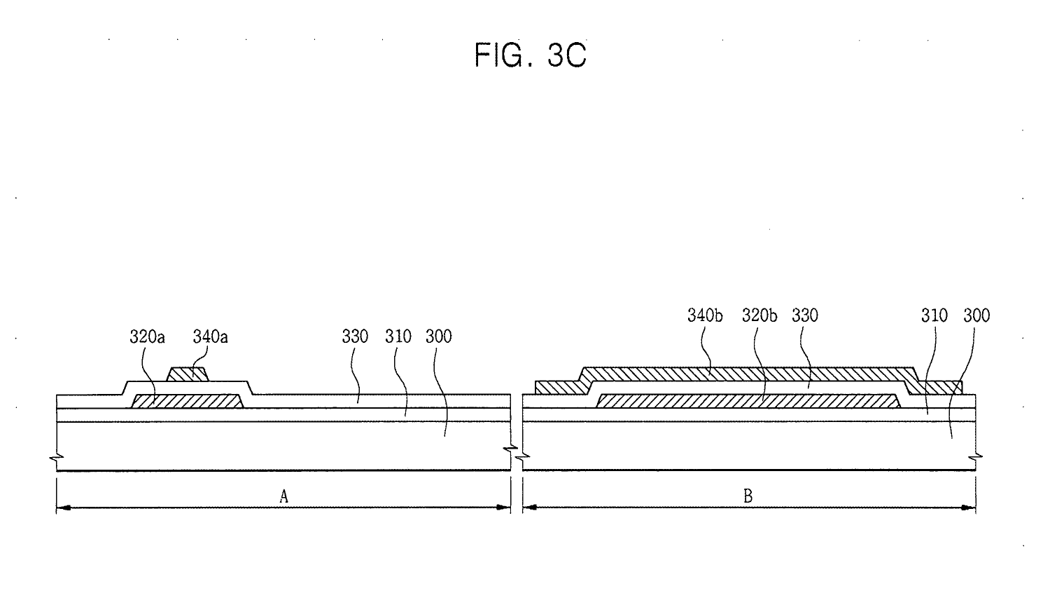

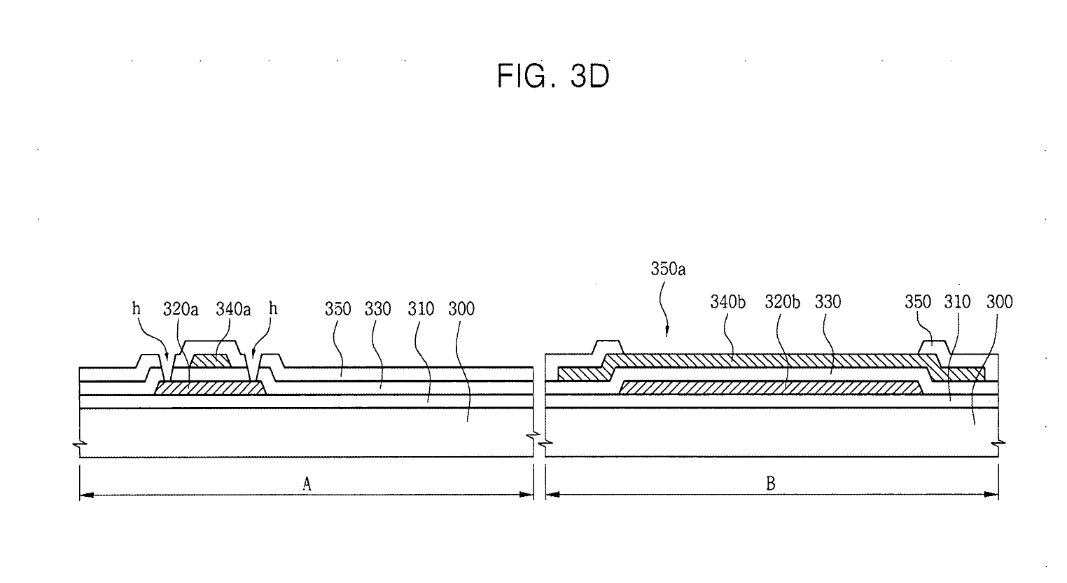

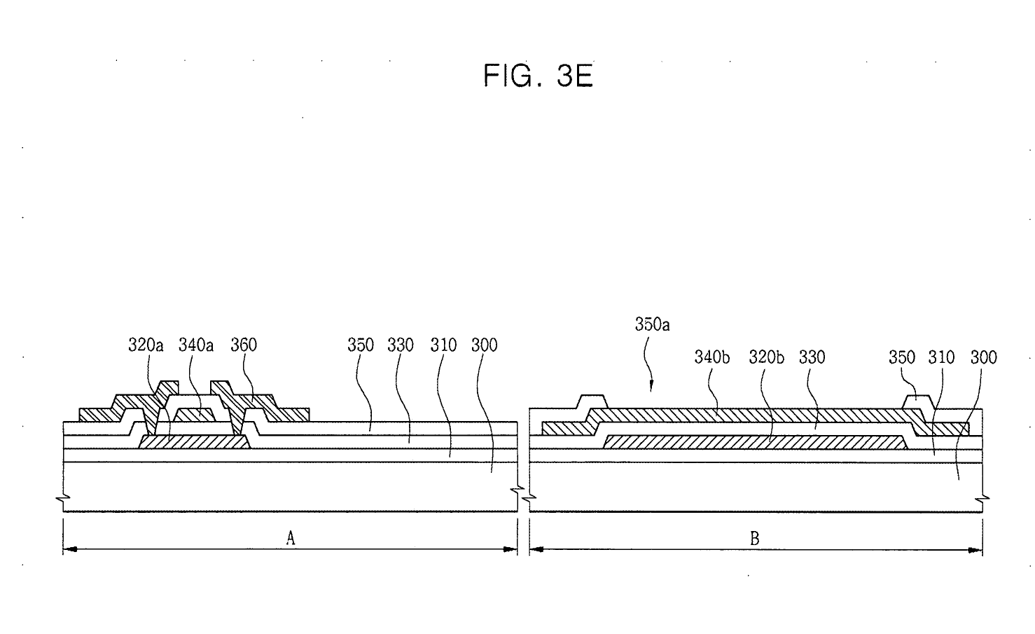

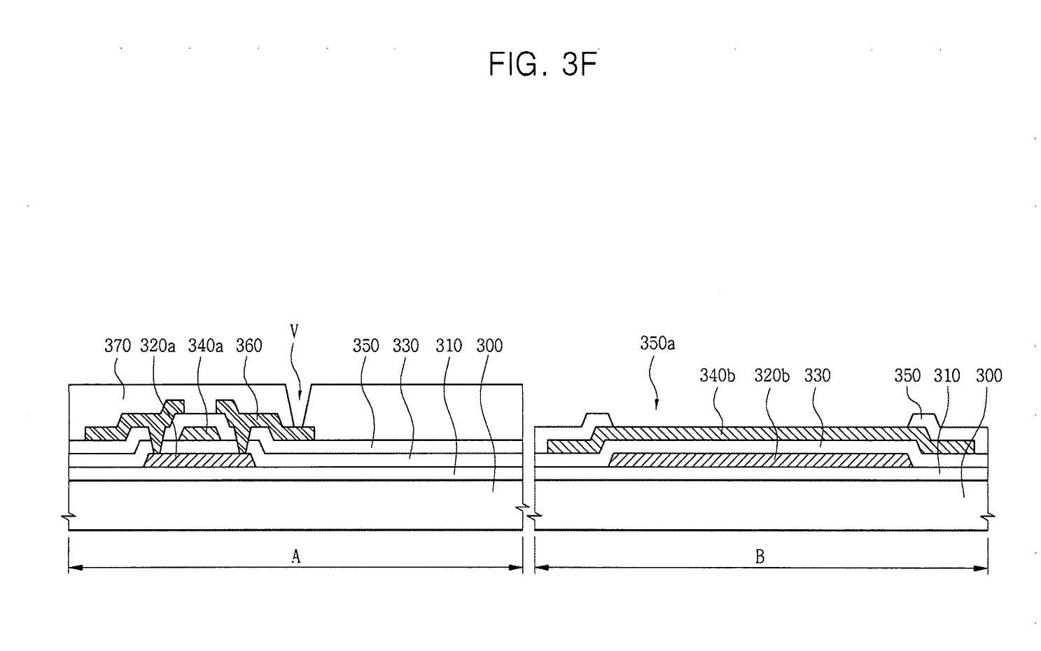

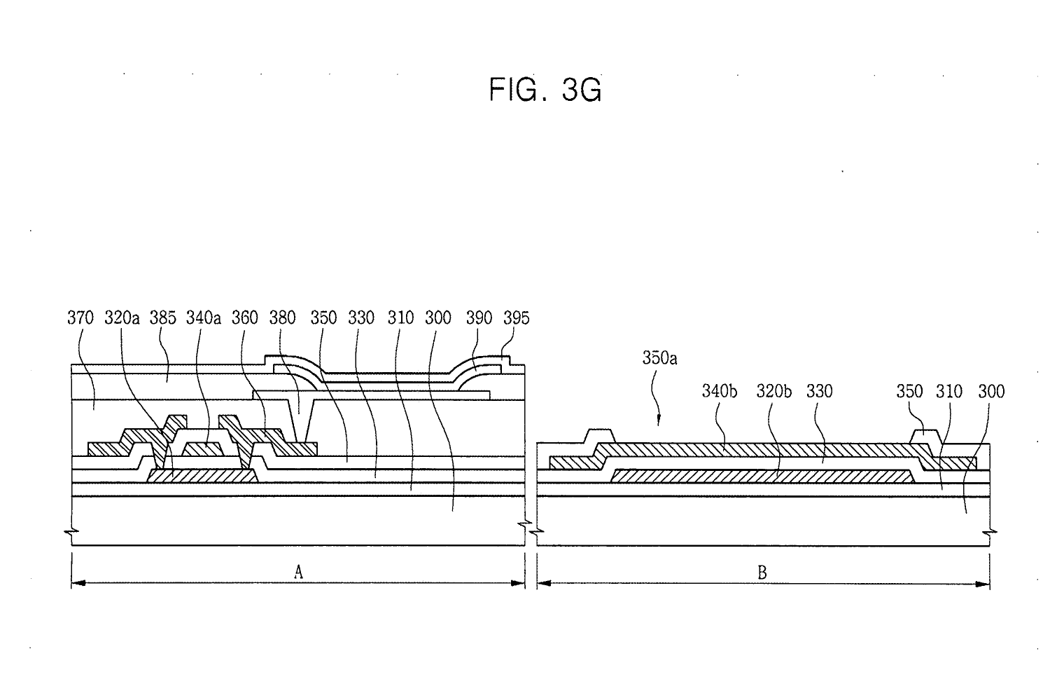

FIGS. 3A through 3G are cross-sectional views showing a process of fabricating an OLED display device having a pad area according to a first exemplary embodiment according to the present invention.

To begin with, referring to FIG. 3A, the insulating substrate 300 includes a pixel area A and a pad area B. A buffer layer 310 is formed on a transparent insulating substrate 300 made out of glass or plastic using a silicon oxide layer, a silicon nitride layer or a combination thereof.

The buffer layer 310 is formed on the entire surface of the substrate 300 having the pixel area A and the pad area B to prevent out-diffusion of moisture or impurities from the underlying substrate 300 and to control a heat transfer rate during crystallization, thereby facilitating the crystallization of a semiconductor layer.

Subsequently, an amorphous silicon layer (not shown) is formed on the buffer layer 310 and crystallized into a polycrystalline silicon layer by one of various crystallization techniques.

Examples of crystallization techniques can include rapid thermal annealing (RTA), solid phase crystallization (SPC), metal induced crystallization (MIC), metal induced lateral crystallization (MILC), super grain silicon (SGS), excimer laser annealing (ELA) and sequential lateral solidification (SLS) techniques.

Here, to effectively increase a roughness of the polycrystalline silicon layer, the crystallization can be performed using a laser, and preferably, by the ELA technique. Compared with other crystallization techniques, the ELA technique can effectively increase the roughness due to protrusions generated on a surface of the polycrystalline silicon layer during crystallization of silicon particles by applying a laser.

Subsequently, the polycrystalline silicon layer (not shown) is patterned to form a polycrystalline silicon layer pattern 320a in the pixel area A and a polycrystalline silicon layer pattern 320b in the pad area B.

Here, the polycrystalline silicon layer pattern 320a in the pixel area A corresponds to a semiconductor layer of a thin film transistor, and the polycrystalline silicon layer pattern 320b in the pad area B, as described above, corresponds to a remaining dummy pattern used to produce roughness on the interconnection layer formed in a subsequent process.

Afterwards, referring to FIG. 3B, a gate insulating layer 330 is formed on the entire surface of the substrate having the polycrystalline silicon layer pattern 320a in the pixel area A and the polycrystalline silicon layer pattern 320b in the pad area B. The gate insulating layer 330 can be a silicon oxide (SiO₂) layer, a silicon nitride (SiNx) layer, or a combination thereof.

Here, as shown in FIG. 2B, because the morphology of the roughness formed on the polycrystalline silicon layer pattern 320b, the gate insulating layer 330 formed on the polycrystalline silicon layer pattern 320b also has a roughness.

Then, referring to FIG. 3C, a gate electrode material is deposited on the gate insulating layer 330 and patterned to form a gate electrode 340a in the pixel area A and an interconnection layer 340b in the pad area B. Here, the gate electrode 340a is located at a specific region corresponding to a channel region of the polycrystalline silicon layer pattern 320a in the pixel area A, which is well known in the art, and thus the detailed description thereof will be omitted. The gate electrode material can be one of aluminum (Al), an Al alloy, molybdenum (Mo) and a Mo alloy.

Meanwhile, an impurity ion is injected into the polycrystalline silicon layer pattern 320a in the pixel area A using the gate electrode 340a in the pixel area as an ion injection mask, thereby forming source and drain regions. Here, the ion injection process can use an n+ or p+ impurity as a dopant, which is well known in the art, and thus the detailed description thereof will be omitted.

Here, as shown in FIG. 2B, because of the morphology of the roughness formed on the gate insulating layer 330, the interconnection layer 340b also has a roughness.

In other words, due to the influence of the morphology of the roughness formed on the polycrystalline silicon layer pattern 320b to the interconnection layer 340b, a surface area of the interconnection layer 340b is increased. As a result, to operate the flat panel display device, parts generating control and data signals are attached to the pad area of the display, and a contact area between these parts and the interconnection layer of the display is increased, resulting in reduced contact resistance.

Subsequently, referring to FIG. 3D, an interlayer insulating layer 350 is formed on the entire surface of the substrate having the gate electrode 340a and the interconnection layer 340b. The interlayer insulating layer 350 can be a silicon oxide (SiO₂) layer, a silicon nitride (SiNx) layer or a combination thereof.

Afterwards, contact holes h exposing a portion of the source and drain regions of the semiconductor layer formed on the pixel area A and an opening 350a exposing a portion of the interconnection layer 340b is formed in the interlayer insulating layer 350 in pad area B. Here, the opening 350a exposing a part of the interconnection layer 340b is formed to surround an edge of the interconnection layer 340b and expose the interconnection layer 340b therethrough. Thus, the pad area according to the present invention is completed. Here, the pad area can be connected to the scan driver 120 of FIG. 1.

Subsequently, referring to FIG. 3E, a conductor material for source and drain electrodes is deposited on the entire surface of the substrate having the pixel area A and the pad area B, and then patterned to form source and drain electrodes 360 in the pixel area A. During this patterning, the material for the source and drain electrodes deposited in the pad area B is completely removed.

The material for the source and drain electrodes can be one of Mo, W, MoW, Al—Nd, Ti, Al, an Al alloy, Ag and an Ag alloy. The material can be formed in a single layer structure, or, to reduce an interconnection resistance, in a double layer structure using a low resistance material such as Mo, Al or Ag or a multi layer structure of, for example, Mo/Al/Mo, MoW/Al—Nd/MoW, Ti/Al/Ti, Mo/Al/Mo, or Mo/Ag alloy/Mo.

Subsequently, referring to FIG. 3F, a planarization layer 370 is formed on the entire surface of the substrate having the pixel area A and the pad area B using an organic material such as resin by spin coating, and then etched in the pixel area A to form a via hole V exposing one of the source and drain electrodes 360. Here, during the formation of the via hole V, the planarization layer deposited in the pad area B is completely removed.

Subsequently, referring to FIG. 3G, on the pixel area A, a first electrode 380, a pixel defining layer 385 exposing a portion of the first electrode 380 and made out of an organic material, an organic layer arrangement 390 formed on the pixel defining layer 385 and including at least an organic emission layer, and a second electrode 395 formed on the organic layer arrangement 390 can be sequentially formed.

To be more specific, the first electrode 380 can be a reflective electrode for a top-emissive OLED display device. The reflective electrode can be made out of Ag, Mg, Al, Pt, Pd, Au, Ni, Nd, Ir, Cr or a combination thereof, and stacking a transparent electrode made out of one of indium tin oxide (ITO), indium zinc oxide (IZO), tin oxide (TO), and zinc oxide (ZnO) on the reflective layer.

Alternatively, the first electrode 380 can be a transparent electrode for a bottom-emissive OLED display device. The transparent electrode can be made out of ITO, IZO. TO or ZnO.

The organic layer arrangement 390 includes at least an emission layer, and can further include at least one of a hole injection layer, a hole transport layer, an electrode transport layer and an electrode injection layer. However, the above-described configuration and material for the organic layer arrangement are not so limited in the present invention.

As a material for the hole transport layer, N,N′-di(naphthalene-1-yl)-N,N′-diphenyl-benzidine (α-NPB) or N,N′-bis(3-methylphenyl)-N,N′-diphenyl-[1,1′-biphenyl]-4,4′-diamine (TPD) can be used. The hole transport layer can be formed to a thickness of 10 to 50 nm. Beyond this range, a hole injecting characteristic can be reduced.

A dopant capable of emitting light due to electron-hole coupling can be added to the hole transport layer in addition to the material for the hole transport layer, and examples of the dopant can include 4-(dicyanomethylene)-2-tert-butyl-6-(1,1,7,7-tetramethyljulolidyl-9-enyl)-4H-pyran (DCJTB), Coumarin 6, rubrene, DCM, DCJTB, perylene, and quinacridone. A content of the dopant is 0.1 to 5 wt % of the total weight of the material for the hole transport layer. As the dopant is added during the formation of the hole transport layer, the color of emitting light can be controlled by a kind and a content of the dopant, and the hole transport layer can have improved thermal stability, thereby extending a lifespan of the device.

The hole injection layer can be formed to a thickness of 30 to 100 nm using a starburst amine-based compound. Beyond this range, the hole injection characteristic can be degraded. Using the hole injection layer, a contact resistance between a counter electrode and the hole transport layer can be reduced, and a hole transport ability of an anode electrode is enhanced due to the hole injection layer, resulting in improving almost all the characteristics of the device.

The material for the emission layer is not particularly limited, but preferably made out of 4,4′-bis(carbazole-9-yl)-biphenyl (CBP). The emission layer can further contain a dopant capable of emitting light due to electron-hole coupling like the hole transport layer described above, and the kind and content of the dopant are almost the same as those for the hole transport layer. The emission layer can be formed to a thickness of 10 to 40 nm.

A material for the electron transport layer can be made out of tris(8-quinolinolate)-aluminum (Alq3) or Almq3, and further contain a dopant capable of emitting light due to electron-hole coupling like the hole transport layer as described above. Here, the kind and content of the dopant can be the same as those for the hole transport layer, and the electron transport layer can be formed to a thickness of 30 to 100 nm. Beyond this range, efficiency and driving voltage can be increased.

A hole barrier layer (HBL) can be further formed between the emission layer and the electron transport layer. The hole barrier layer functions to prevent excitons formed from a phosphorescent emitting material from moving to the electron transport layer, or prevent holes from moving to the electron transport layer. The hole barrier layer can be made out of BAlq.

The electron injection layer can be formed to a thickness of 0.1 to 10 nm using LiF. Beyond this range, the electron injection layer has an increased driving voltage.

In the top-emissive OLED display device, the second electrode 395 formed on the organic layer arrangement can be made out of a semi-transmissive cathode, or by stacking a semi-transmissive cathode and a transmissive cathode.

The semi-transmissive cathode can be formed thinly to a thickness of 5 to 30 nm using one of Li, Ca, LiF/Ca, LiF/Al, Al, Mg and an Mg alloy. In the case in which the semi-transmissive cathode is formed and then the transmissive cathode is stacked thereon, the semi-transmissive cathode is formed using a metal having a low work function such as Li, Ca, LiF/Ca, LiF/Al, Al, Mg or a Mg alloy, and an additional layer is made out of a material having a low resistance characteristic, such as ITO or IZO. Here, when the thickness of the semi-transmissive cathode is less than 5 nm, electrons can not be injected at a low voltage, and when the thickness of the semi-transparent cathode is more than 30 nm, transmittance is significantly reduced. A total combined thickness of the semi-transmissive cathode and the transmissive cathode can be 10 to 400 tun.

In a bottom emission OLED display device, the second electrode 395 can be a reflective electrode. The reflective electrode can be made out of one selected from the group consisting of Li, Ca, LiF/Ca, LiF/Al, Al, Mg and a Mg alloy. However, in the present invention, the materials for the first electrode, organic layer arrangement and second electrode are not limited.

Thus, the OLED display device having a pad area according to the present invention is completed.

While, in FIGS. 3A through 3G, the insulating layer of FIG. 2A is a gate insulating layer, an interconnection layer composed of a conductor material on the insulating layer is made out of a gate electrode material, and a protective layer is an interlayer insulating layer, the insulating layer of FIG. 2A can instead be an interlayer insulating layer, the interconnection layer can instead be made out of a material for source and drain electrodes, and the protective layer can instead be a planarization layer.

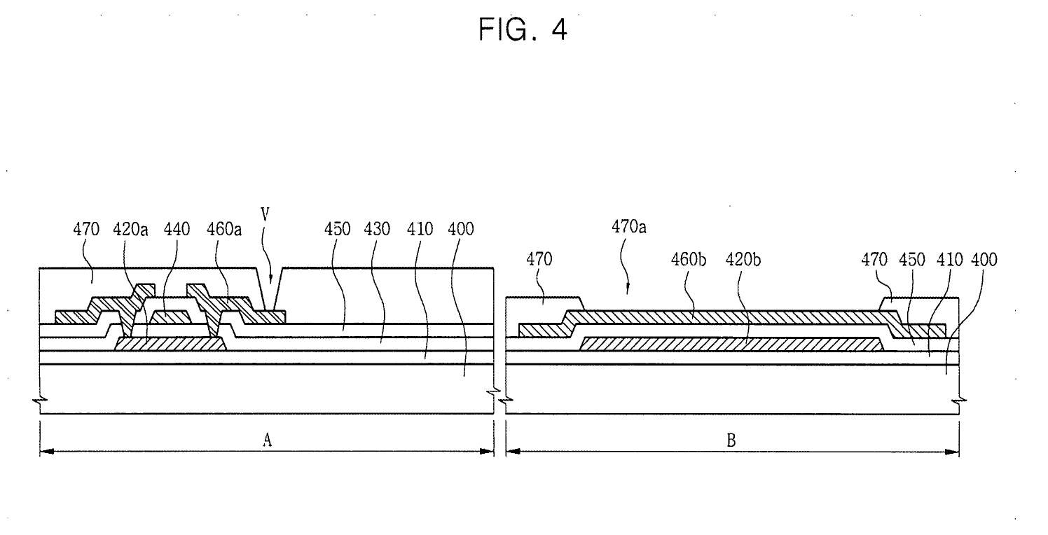

The above-mentioned configuration will be described with reference to FIG. 4. FIG. 4 is a cross-sectional view of an OLED display device having a pad area of a second exemplary embodiment according to the present invention. The OLED display device having the pad area of the second exemplary embodiment of the present invention can be the same as that of the first exemplary embodiment of the present invention except for those features to be specifically described below.

Referring to FIG. 4, in a pixel area A, a buffer layer 410 is formed on a substrate 400 as in the first exemplary embodiment, and a polycrystalline silicon layer pattern is formed on the buffer layer 410 as a semiconductor layer 420a. Here, in the pad area B, the buffer layer 410 is formed on the substrate 400 as in the first exemplary embodiment, and the polycrystalline silicon layer pattern 420b is formed on the buffer layer 410.

Subsequently, in the pixel area A, as in the first exemplary embodiment, a gate insulating layer 430 is formed on the semiconductor layer 420a, and a gate electrode 440 is formed on the gate insulating layer. However, in the pad area B, unlike the first exemplary embodiment, the gate insulating layer and a material for the gate electrode are completely removed.

An interlayer insulating layer 450 is formed on the entire surface of the substrate having the gate electrode, and unlike the first exemplary embodiment, the interlayer insulating layer is not be removed in the pad area B, and instead serves as an insulating layer as shown in FIG. 2A.

A contact hole is formed in the interlayer insulating layer 450, and a material for source and drain electrodes is applied to be electrically connected to source and drain regions of the silicon layer pattern in the pixel area. Afterwards, in the pixel area, the material for the source and drain electrodes is patterned, thereby forming the source and drain electrodes 460a electrically connected to the source and drain regions. In the pad area, an interconnection layer 460b is formed on interlayer insulating layer 450 to correspond to the polycrystalline silicon layer pattern 420b.

To be specific, although the interconnection layer is formed using the gate electrode material in the first exemplary embodiment, it is formed using the material for the source and drain electrodes in the second exemplary embodiment.

Subsequently, a planarization layer 470 is formed on the entire surface of the substrate having the source and drain electrodes 460a and the interconnection, layer 460b, and etched in the pixel area A to form via hole V exposing one of the source and drain electrodes 460a, and etched in the pad area B to form an opening 470a exposing a portion of the interconnection layer 460b. Thus, the pad area of the second exemplary embodiment according to the present invention is completed.

Here, the pad area of the second exemplary embodiment can be connected to the data driver 130 or common power bus line 140 as shown in FIG. 1.

Consequently, as a polycrystalline silicon layer pattern 420b remains under an interconnection layer 460b in a pad area B so that the pad area B is capable of having an increased interconnection layer 460b surface area by producing polycrystalline silicon layer pattern 420b to have a rough surface.

In addition, as the surface area of the interconnection layer according to the present invention is increased, a contact area between parts configured to operate a flat panel display device and the interconnection layer is increased, thereby reducing a contact resistance.

Although the present invention has been described with reference to predetermined exemplary embodiments thereof, it will be understood by those skilled in the art that a variety of modifications and variations can be made to the present invention without departing from the spirit or scope according to the present invention defined in the appended claims and their equivalents.

What is claimed is:

1. A pad area, comprising:
a substrate;
a silicon layer pattern arranged on the substrate;
an insulating layer arranged on the silicon layer pattern;
an interconnection layer arranged on the insulating layer; and
a protective layer surrounding an edge of the interconnection layer and having an opening exposing the interconnection layer.

2. The pad area of claim 1, wherein the silicon layer pattern, the insulating layer and the interconnection layer have uneven surfaces.

3. The pad area of claim 1, wherein the silicon layer pattern is a polycrystalline silicon layer pattern.

4. An organic light emitting diode (OLED) display device comprising a substrate having a pixel area and a pad area, the pad area comprising:
a silicon layer pattern arranged on the substrate;
an insulating layer arranged on the silicon layer pattern;
an interconnection layer arranged on the insulating layer; and
a protective layer surrounding an edge of the interconnection layer and having an opening exposing the interconnection layer.

5. The OLED display device of claim 4, wherein the silicon layer pattern, the insulating layer and the interconnection layer have uneven surfaces.

6. The OLED display device of claim 4, wherein the pixel area comprises:
a silicon layer pattern arranged on the substrate and having source and drain regions;
a gate insulating layer arranged on an entire surface of the substrate having the silicon layer pattern;
a gate electrode arranged on the gate insulating layer;
an interlayer insulating layer arranged on the gate electrode; and
source and drain electrodes electrically connected to the source and drain regions respectively of the silicon layer pattern in the pixel area through contact holes arranged in the interlayer insulating layer.

7. The OLED display device of claim 6, wherein the insulating layer in the pad area is the gate insulating layer, and the interconnection layer in the pad area is comprised of a same material as that of the gate electrode.

8. The OLED display device of claim 6, wherein the insulating layer in the pad area is the interlayer insulating layer, and the interconnection layer in the pad area is comprised of a same material as that of the source and drain electrodes.

9. The OLED display device of claim 4, wherein the silicon layer pattern is a polycrystalline silicon layer pattern.

10. A method of fabricating an organic light emitting diode (OLED) display device, comprising:
providing a substrate having a pixel area and a pad area;
forming an amorphous silicon layer on an entire surface of the substrate;
forming a polycrystalline silicon layer by crystallizing the amorphous silicon layer;
forming polycrystalline silicon layer patterns at predetermined regions of the pixel and pad areas by patterning the polycrystalline silicon layer, the polycrystalline silicon layer pattern in the pixel area having source and drain regions and a channel region;
forming a gate insulating layer on the entire surface of the substrate having the polycrystalline silicon layer patterns;
applying a gate electrode material on the gate insulating layer; and
forming a gate electrode corresponding to the channel region of the polycrystalline silicon layer pattern in the pixel area and an interconnection layer corresponding to the polycrystalline silicon layer pattern in the pad area by patterning the gate electrode material.

11. The method of claim 10, wherein the crystallizing the amorphous silicon layer into the polycrystalline silicon layer is performed using a laser.

12. The method of claim 11, wherein the crystallizing is performed by an excimer laser annealing (ELA) technique.

13. The method of claim 10, wherein the interconnection layer has an uneven surface.

14. A method of fabricating an OLED display device, comprising:
providing a substrate having a pixel area and a pad area;
forming an amorphous silicon layer on an entire surface of the substrate;
forming a polycrystalline silicon layer by crystallizing the amorphous silicon layer;
forming polycrystalline silicon layer patterns in predetermined regions of the pixel and pad areas respectively by patterning the polycrystalline silicon layer, the polycrystalline silicon layer pattern in the pixel area having source and drain regions;
forming an interlayer insulating layer on the entire surface of the substrate having the polycrystalline silicon layer patterns;
applying a material for source and drain electrodes to the pixel area and the pad area; and
forming the source and drain electrodes electrically connected to the source and drain regions respectively of the polycrystalline silicon layer pattern in the pixel area through contact holes formed in the interlayer insulating layer and forming an interconnection layer corresponding to the polycrystalline silicon layer pattern in the pad area by patterning the material for source and drain electrodes.

15. The method of claim 14, wherein the crystallizing the amorphous silicon layer into the polycrystalline silicon layer is performed using a laser.

16. The method of claim 15, wherein the crystallizing is performed by an excimer laser annealing technique.
